(19) United States
(12) Patent Application Publication
(10) Pub. No.: US 2006/0087037 A1
(43) Pub. Date: Apr. 27, 2006

(54) Substrate structure with embedded chip of semiconductor package and method for fabricating the same

(75) Inventor: Shih-Ping Hsu, Hsin-chu (TW)

Correspondence Address: Mr. William F. Nixon;SQUIRE SANDERS & DEMPSEY LLP, 14th Floor, 8000 Towers Crescent Drive, Tysons Corner, VA, 22182-2700, US

(73) Assignee: Phoenix Precision Technology Corporation

(21) Appl. No.: 11/025,015

(22) Filed: Dec. 30, 2004

(30) Foreign Application Priority Data
Oct. 22, 2004 (TW) 093132134

(51) Int. Cl. H01L 23/495

(52) U.S. Cl. 257/738

(57) ABSTRACT

A substrate structure with embedded chips of a semiconductor package and a method for fabricating the same are proposed. First of all, a carrier structure having a first carrier plate and a second carrier plate being directly formed on the first carrier plate is provided. The second carrier plate is provided with at least an opening. Then, a non-active surface of at least a semiconductor chip is mounted onto the first carrier plate and embedded in the opening of the second carrier plate. A dielectric layer is subsequently formed on a surface of the chip and the second carrier plate, and the material of the dielectric layer is filled in the opening of the second carrier plate. Afterwards, a plurality of vias is formed penetrating through the dielectric layer to expose conductive pads located on an active surface of the chip. A circuit layer and conductive vias are then respectively formed on a surface and penetrating through the dielectric layer, such that the circuit layer can be electrically connected to the conductive pad located on the chip by the means of the conductive via. Finally, conductive elements are provided on a surface of the circuit layer, so that the semiconductor chip embedded in the carrier plate can be electrically connected to an external device.

### FIELD OF THE INVENTION

The present invention relates to a substrate structure with embedded chips of a semiconductor package and a method for fabricating the same, and more particularly, to a semiconductor package structure which integrates chips and carriers and a method for fabricating the same.

### BACKGROUND OF THE INVENTION

Along with the blooming development of electronic industry, electronic products are gradually becoming more multi-functional and high efficient. In order to satisfy the requirements of high integration and miniaturization for semiconductor packages, a circuit board for carrying active/passive components and circuits is developed from a single-layer board into a multi-layer board, which is accomplished using the interlayer connection technique to enlarge usable area of the circuit board within limited space, so as to incorporate integrated circuits of high electronic density in the circuit board.

However, as layers of conductive circuits and density of electronic elements on the circuit board are increased to meet the requirement of integration, heat generated by a semiconductor chip during operation is dramatically increased. If heat cannot be released immediately, the semiconductor package might be over heated to therefore damage the chip. Recently, a ball grid array (BGA) structure is not able to satisfy the requirements of electric performances and heat dissipation when the number of leads exceeds 1500 pin and the frequency is over 5 GHz. A flip-chip ball grid array (FCBGA) structure is applicable to products with more leads and a higher frequency. However, an overall packaging cost is very high and there are still many technique limitations. Particularly, referring to the technique of electrical connection, materials used to perform electrical connection including soldering materials such as lead (Pb) are prohibited due to environmental protection. Instead, other materials that cause unstable electrical, mechanical and physical properties are used.

Accordingly, a new method in which the semiconductor chip is directly embedded in a substrate has been disclosed. Referring to FIG. 1, U.S. Pat. No. 6,709,898 has disclosed a die-in-heat spreader microelectronic package which comprises a heat spreader 102 having at least a recess 104, a microelectronic die 114 whose non-active surface 118 is mounted in the recess 104 using a thermally conductive adhesive material 120, and a build-up circuit structure 122 formed on the heat spreader 102 and the microelectronic die 114 by a build-up technique.

FIG. 2 is a cross-sectional view of the heat spreader 102. The recess 104 of the heat spreader 102 is extended from an upper surface of the heat spreader 102 to reach a certain deepness of the heat spreader 102.

Referring to FIG. 3, the heat spreader 102 for supporting the microelectronic die 114 is made of a single metal material. Although the recess 104 for mounting the microelectronic die 114 can be formerly fabricated using half etching technique, the deepness of each of the recesses 104 formed on the surface of the heat spreader 102 is inconsistent and a planar surface cannot be achieved as it is difficult to control homogeneity of the half etching technique. Therefore, mounting of semiconductor elements and connection of joints can be problems. Additionally, it is even more difficult to control the height and homogeneity, so as to affect the fabrication quality of the subsequent build-up circuit structure and reliability of electrical connection.

### SUMMARY OF THE INVENTION

In light of the prior-art drawbacks, a primary objective of the present invention is to provide a substrate structure with embedded chips of a semiconductor package and a method for fabricating the same, by which semiconductor chips and chip carriers can be simultaneously integrated.

Another objective of the present invention is to provide a substrate structure with embedded chips of a semiconductor package and a method for fabricating the same, by which production yields of fabrication of embedding chips into a carrier can be improved.

Still another objective of the present invention is to provide a substrate structure with embedded chips of a semiconductor package and a method for fabricating the same, by which uniformity of surface integration between a carrier and a chip can be well maintained.

A further objective of the present invention is to provide a substrate structure with embedded chips of a semiconductor package and a method for fabricating the same, by which a fabrication quality of a subsequent build-up circuit structure and reliability of electrical connection can be improved.

A further objective of the present invention is to provide a substrate structure with embedded chips of a semiconductor package and a method for fabricating the same, by which a warpage problem of a semiconductor device can be solved.

A further objective of the present invention is to provide a substrate structure with embedded chips of a semiconductor package and a method for fabricating the same, by which heat dissipation efficiency of the chip can be improved.

In accordance with the above and other objectives, the present invention proposes a substrate structure with embedded chips of a semiconductor package and a method for fabricating the same. First of all, a carrier structure comprising a first carrier plate and a second carrier plate being directly formed on the first carrier plate is provided. The second carrier plate is provided with at least an opening penetrating through a surface thereof. Then, a non-active surface of at least a semiconductor chip is mounted onto the first carrier plate and embedded in the opening of the second carrier plate. Build-up circuits are subsequently fabricated, such that a dielectric layer is formed on a surface of the chip and the second carrier plate, and materials of the dielectric layer are filled in the opening of the second carrier plate. Afterwards, a plurality of vias is formed penetrating through the dielectric layer to expose a conductive pad located on an active surface of the chip. Finally, a patterned circuit layer is formed on the dielectric layer and conductive vias are formed penetrating through the dielectric layer, such that the patterned circuit layer can be electrically connected to the conductive pad located on the chip by the means of the conductive via. Multilayer of build-up circuit structures can be subsequently fabricated, and a plurality of conductive elements can be mounted on a surface circuit layer of the build-up circuit structure, so that the semiconductor package structure can be electrically connected to an external device.

After fabrication of the build-up circuit layer has been completed, a resist layer can be covered on the build-up circuit layer. Then, the first carrier plate for previously mounting the chip is removed by etching technique, such that a back surface of the chip can be exposed for further directly attaching other heat dissipation devices to improve heat dissipation efficiency. Meanwhile, an overall thickness of the package structure can be reduced, so as to meet the requirement of miniaturization.

Moreover, after fabrication of a first build-up circuit layer has been completed, a resist layer can be covered on the circuit layer. Then, the first carrier plate for previously mounting the chip is removed to expose the chip. Surface treatment is performed on an exposed surface of the chip and a surface of the carrier plate on the same side. Subsequently, a metal layer is formed on the treated surface of the chip and the carrier plate during subsequent fabrication of the build-up circuit, such that the chip can be directly contacted to the metal layer to improve heat dissipation efficiency.

The present invention also proposes a substrate structure with embedded chips of a semiconductor package using the foregoing fabrication method, which comprises a carrier structure comprising a first carrier plate and a second carrier plate being directly formed on the first carrier plate, wherein the second carrier plate is provided with at least an opening for subsequently receiving various electronic elements; at least a semiconductor chip embedded in the opening penetrating through the second carrier plate and mounted on the first carrier plate, wherein the semiconductor chip is provided with conductive pads on a surface thereof; at least a build-up circuit structure formed on the second carrier plate, wherein conductive vias are formed penetrating through the build-up circuit structure to electrically connect the conductive pad located on the semiconductor chip; and a plurality of conductive elements formed on a surface circuit layer of the build-up circuit structure.

Referring to another preferred embodiment, the substrate structure with embedded chips of a semiconductor package proposed in the present invention comprises a semiconductor chip having conductive pads on a surface thereof; a carrier plate for receiving the periphery of the semiconductor chip; at least a build-up circuit structure formed on the carrier plate embedded with the semiconductor chip, wherein conductive vias are formed penetrating through the build-up circuit structure to electrically connect the conductive pad located on the semiconductor chip, so as to expose a surface of the chip free of attaching the conductive pad; and a plurality of conductive elements formed on a surface circuit layer of the build-up circuit structure. Additionally, a metal layer can be attached to a surface of the semiconductor chip free of electrically connecting the build-up circuit structure.

Referring to the substrate structure with embedded chips of a semiconductor package and the method for fabricating the same proposed in the present invention, at least a semiconductor chip is attached to a heat dissipating carrier structure by the means of a thermally conductive adhesive layer, such that heat generated by the semiconductor chip during operation can be effectively dissipated. Further, the semiconductor chip is embedded in the opening penetrating through the second carrier plate of the carrier structure, such that an overall thickness of the semiconductor device can be reduced to meet the requirement of miniaturization. Also, in the present invention, at least a build-up circuit structure is directly formed on the carrier structure embedded with the semiconductor chip, and the build-up circuit structure can be electrically connected to the conductive pad located on the semiconductor chip by the means of the conducive via. Moreover, the conductive elements such as solder balls, leads or metal bumps can be provided on the outer surface of the build-up circuit structure, such that the semiconductor package structure can be electrically connected to an external device. As the carrier structure of the present invention consists of two different materials such as two different metal layers, a flat integration surface can be formed in the second carrier plate using an etching or electroplating technique. Alternatively, the carrier structure can be consisted of a ceramic layer and a metal layer. An opening can be precast penetrating through the metal layer by the means of the ceramic layer or an opening can be precast penetrating through the ceramic layer by the means of the metal layer using an etching process, such that a flat integration surface can be formed in the second carrier plate of the carrier structure. Therefore, an electronic element such as the semiconductor chip can be stably and consistently mounted on the carrier structure, such that production yields of fabricating the carrier structure embedded with chips can be improved while well maintaining uniformity of the integration surface between the carrier structure and the chip. Furthermore, a warpage problem of the semiconductor device can be solved using characteristics of different materials, so as to improve a fabrication quality of the subsequent build-up circuit structure and reliability of electrical connection.

Referring to the other embodiment of the present invention, the first carrier plate can be removed to directly expose the chip, such that the overall thickness of the semiconductor package structure can be reduced to effectively meet the requirement of miniaturization while directly attaching other external heat dissipating devices to improve heat dissipation efficiency.

The present invention is capable of integrating the heat dissipating carrier structure, the semiconductor chip and the build-up circuit structure while incorporating techniques of fabricating the semiconductor package, so that drawbacks caused by the semiconductor packaging technique known in the prior-art can be eliminated while solving a surface integration problem of the semiconductor device. Therefore, the present invention is able to provide a substrate structure embedded with chips characterized with advantages including a good quality, high production yield, low cost and good reliability.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a semiconductor device according to U.S. Pat. No. 6,709,898;

FIG. 2 is a cross-sectional view of a heat spreader according to U.S. Pat. No. 6,709,898;

FIG. 3 is a partially cross-sectional view showing drawbacks caused by the heat spreader when embedding chips as shown in FIG. 2;

FIG. 4A to FIG. 4J are cross-sectional views showing fabrication of a substrate structure with embedded chips of a semiconductor package according to the first embodiment of the present invention;

FIG. 5A to FIG. 5J are cross-sectional views showing fabrication of a substrate structure with embedded chips of a semiconductor package according to the second embodiment of the present invention;

FIG. 5I′ is a cross-sectional view showing a metal layer being attached to an exposed surface of a chip in a substrate structure with embedded chips of a semiconductor package according to the present invention; and

FIG. 5J′ is a cross-sectional view showing conductive elements being provided on a surface of a circuit layer in a substrate structure embedded with a chip and attached with a metal plate in a semiconductor package according to the present invention.

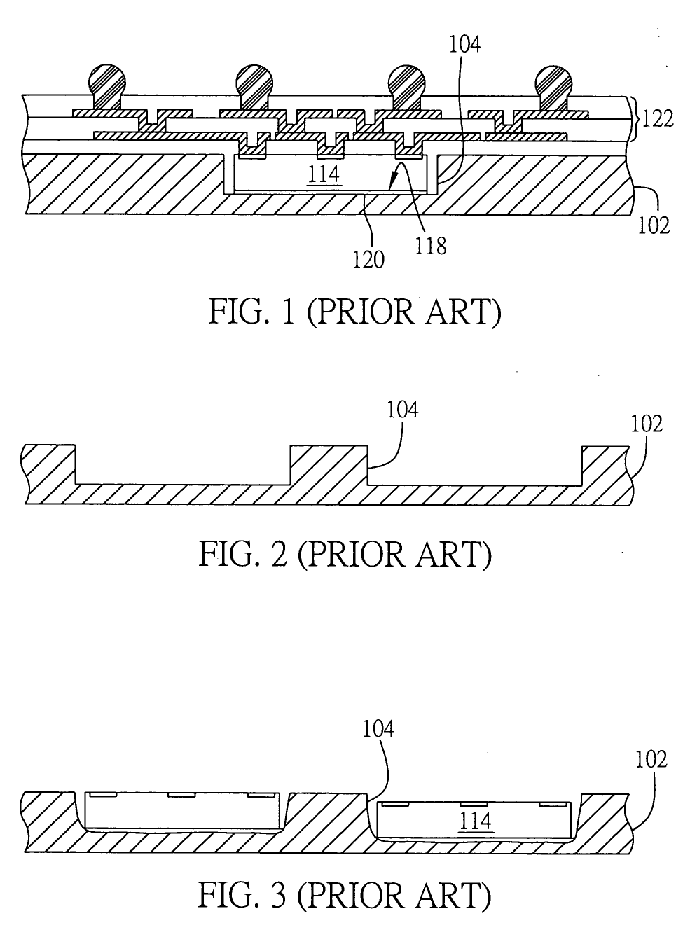

### DETAILED DESCRIPTION OF THE EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

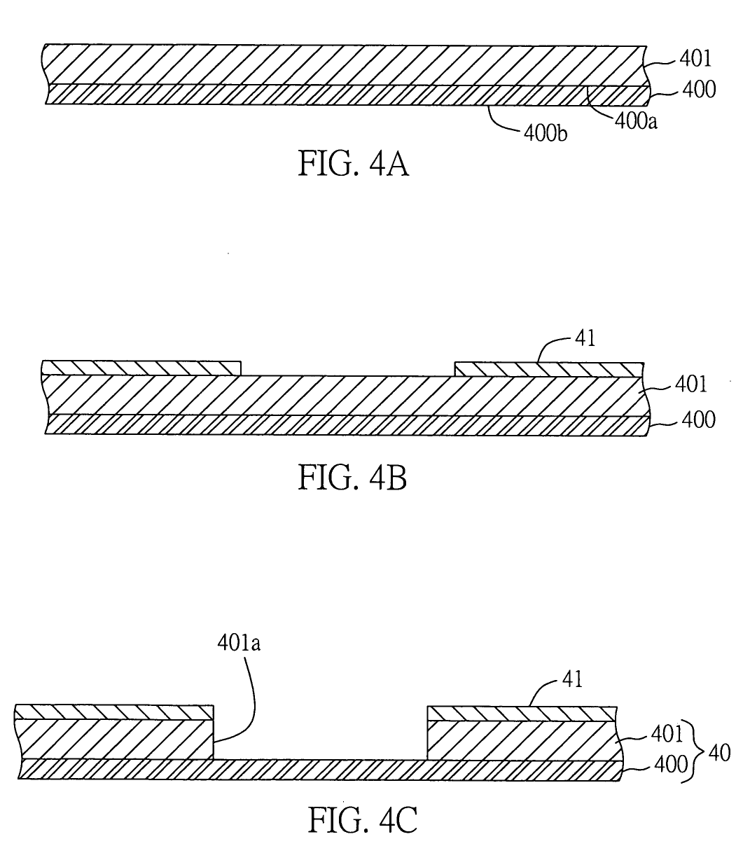

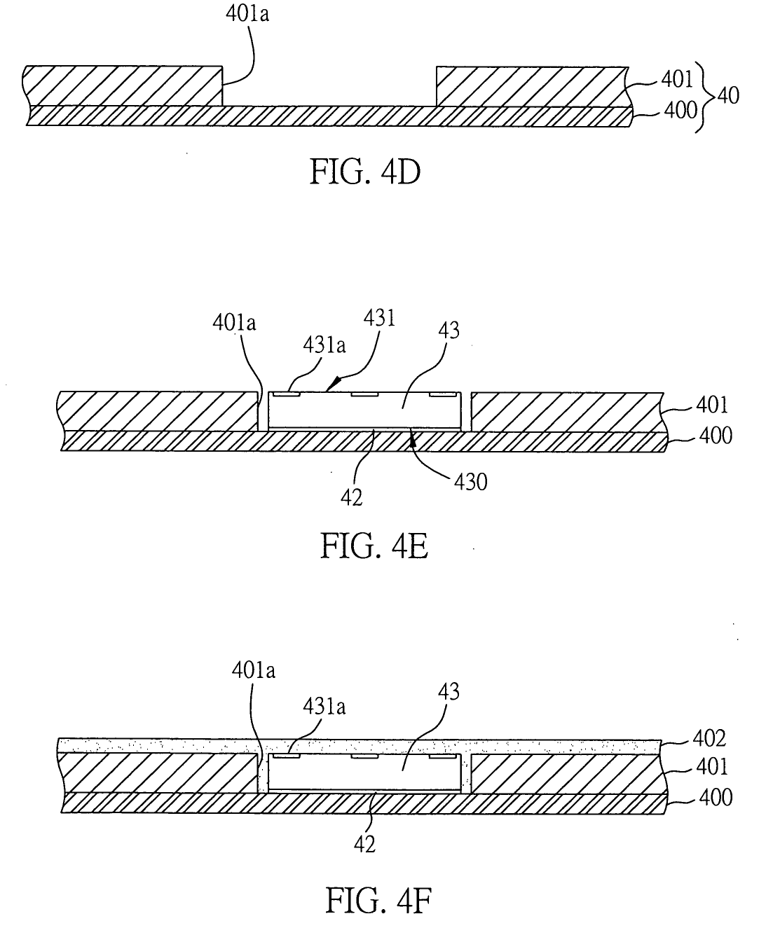

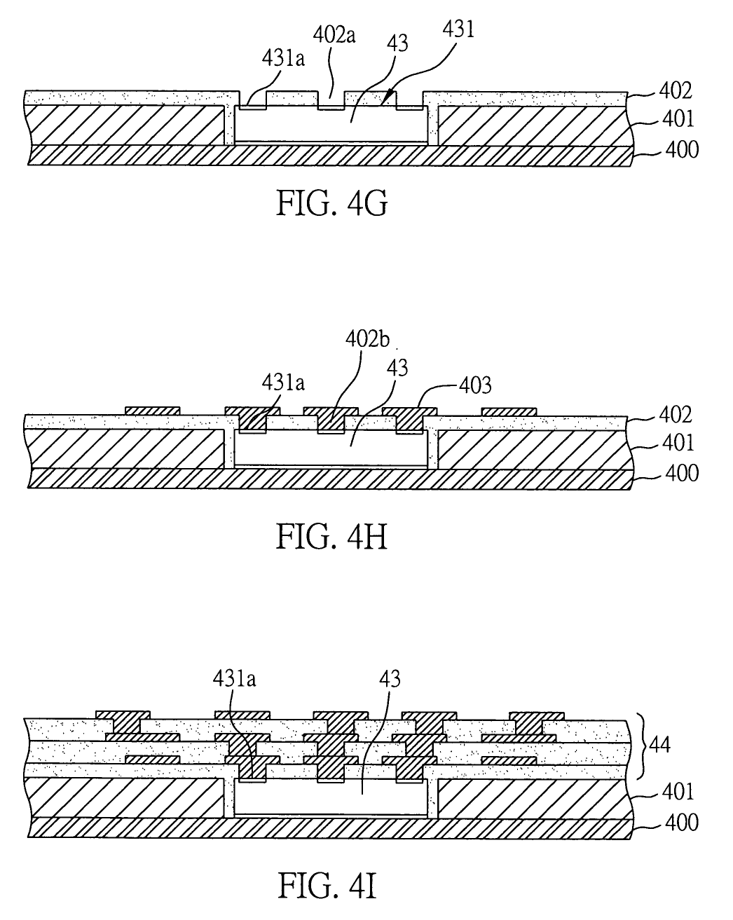

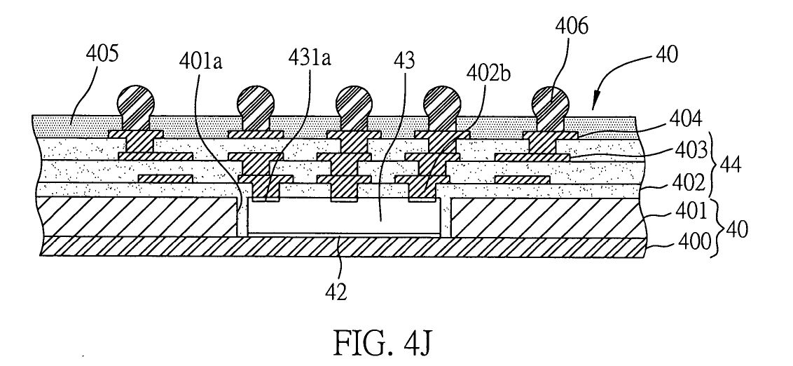

A preferred embodiment of a method for fabricating a substrate structure with embedded chips of a semiconductor package proposed in the present invention is described in detail with reference to FIG. 4A to FIG. 4J. What needs to be concerned here is that these drawings are simplified schematic diagrams, and thus only constructs relevant to the present invention are illustrated. Also, these constructs are not drawn according to actual amounts, shapes and dimensions. Actually, the amount, shape and dimension are an optional design and the arrangements of the constructs may be very complex in the reality.

Referring to FIG. 4A, first of all, a first carrier plate 400 and a second carrier plate 401 are provided. The first carrier plate 400 is provided with an upper surface 400a and a corresponding lower surface 400b. The second carrier plate 401 can be formed on the upper surface 400a by a heating, pressing or electroplating process. The material of the first carrier plate 400 is different from that of the second carrier plate 401, and the combination of the materials can be optional and selected from the group consisting of copper/nickel (Cu/Ni), copper/aluminum (Cu/Al), aluminum/nickel (Al/Ni), nickel/aluminum (Ni/Al), stainless steel/copper, copper/stainless steel and aluminum/stainless steel. If the first carrier plate and the second carrier plate are made of a metal and a ceramic, the metal can be optionally selected from the group consisting of copper (Cu), aluminum (Al), nickel (Ni) and stainless steels, and the ceramic can be optionally selected from aluminum oxide or aluminum nitride. Further, the thickness of the first and second carrier plates 400 and 401 can be determined depending on practical requirements.

Referring to FIG. 4B, a patterned resist layer 41 is formed on the second carrier plate 401. The resist layer 41 can be a photoresist layer such as a dry film or liquid photoresist formed on a surface of the second carrier plate 401 using printing, spin-coating or attaching techniques. Subsequently, the resist layer is patterned using exposing and developing techniques, such that the resist layer 41 partially covers the second carrier plate 401.

Referring to FIG. 4C, an etching process is performed and the first carrier plate 400 is used as an etching blocking layer. The second carrier plate 401 is optionally etched using an appropriate etchant to remove the second carrier plate 401 that is not covered by the resist layer 41, such that an opening 401a penetrating through the second carrier plate 401 is formed. Thus, a carrier structure 40 having a plurality of openings on a surface thereof for subsequently mounting electronic elements is accomplished. As the carrier structure 40 consists of two different metal layers, a flat integration surface between the first carrier plate 400 and the second carrier plate 401 of the carrier structure 40 can be achieved, so that the electronic element such as the semiconductor chip can be stably and consistently mounted on the carrier structure 40. Therefore, production yields of fabricating the carrier structure embedded with chips can be improved while well maintaining uniformity of the integration surface between the carrier structure and the chip. Furthermore, a fabrication quality of a subsequent build-up circuit structure and reliability of electrical connection can also be improved. Moreover, referring to the foregoing fabrication method of the carrier structure 40 consisted of two carrier plates made of metals, the opening with the flat integration surface is formed by an optional etching process. Alternatively, a patterned resist layer (not shown) can also be initially formed on the first carrier plate 400. Then, a second carrier plate 401 is formed on surfaces of the first carrier plate 400 free of being subsequently provided with electronic elements by an electroplating process, such that a flat integration surface can be formed between the first carrier plate 400 and the second carrier plate 401.

Referring to FIG. 4D, the resist layer 41 can be removed using a photoresist-stripping process. The process of removing the resist layer 41 is known in the prior-art, and thus is not further described. If the first and second carrier plates are optionally made of a metal and a ceramic, an opening can be formed penetrating through the ceramic using a precast-sintering process, such that a double-layered carrier structure as shown in FIG. 4D can be fabricated. Additionally, the second carrier plate is directly formed on the first carrier plate without using an attaching method.

Referring to FIG. 4E, a non-active surface 430 of a semiconductor chip 43 is mounted on the first carrier plate 400 and embedded in the opening 401a of the second carrier plate 401 using a thermally conductive adhesive layer 42. The dimension of the opening 401a is designed depending on the dimension of the semiconductor chip 43. Furthermore, a plurality of conductive pads 431a is provided on an active surface 431 of the chip 43.

Referring to FIG. 4F, a dielectric layer 402 is formed on the active surface 431 of the semiconductor chip 43 and the second carrier plate 401 and filled in the opening 401a penetrating through the second carrier plate. The dielectric layer can be selected from the group consisting of non-photoimageable resins and epoxy resins such as prepegs and film typed BT, ABF, PPE, PTFE and the like, or photoimageable resins.

Referring to FIG. 4G, a plurality of vias 402a can be formed penetrating through the dielectric layer 402 to expose the conductive pad 431a located on the active surface 431 of the chip 43 using laser drilling or plasma etching techniques. Alternatively, the via 402a can be formed by exposing and developing processes if the dielectric layer is a photoimageable resin.

Referring to FIG. 4H, a patterned circuit layer 403 is formed on the dielectric layer 402. Subsequently, a conductive via 402b is formed corresponding to the via 402a, such that the patterned circuit layer 403 can be electrically connected to the conducive pad 431a located on the chip 43 by the means of the conductive via 402b. The structure of the conductive via can be a fully filled conductive material (such as a filled Cu via) or a partially filled conductive material (such as Cu covered general via layer). The fully filled conductive material is capable of improving electrical properties and heat dissipation efficiency.

Referring to FIG. 4I, build-up circuits can be formed on the carrier structure 40, such that a build-up circuit structure 44 can be formed on the carrier structure 40 embedded with the semiconductor chip 43, and the build-up circuit structure 44 can be electrically connected to the conductive pad 431a located on the chip 43.

Referring to FIG. 4J, a patterned solder mask layer 405 having a plurality of openings is formed on an outer surface of the build-up circuit structure 44, such that conductive pads 404 located on the outer surface of the build-up circuit structure 44 are exposed. Subsequently, a plurality of conductive elements such as solder balls 406, leads or metal bumps are formed on the conductive pad 404 located on the outer surface of the build-up circuit structure 44, so that the semiconductor chip 43 embedded in the carrier structure 40 can be electrically connected to an external device.

Therefore, referring to FIG. 4J, the substrate structure with embedded chips of the semiconductor package fabricated by the foregoing method proposed in the present invention comprises a carrier structure 40 comprising a first carrier plate 400 and a second carrier plate 401 directly formed on the first carrier plate 400, wherein the second carrier plate 401 is provided with at least an opening 401a; at least a semiconductor chip 43 mounted on the first carrier plate 400 and embedded in the opening 401a penetrating through the second carrier plate 401 by a thermally conductive adhesive layer 402; at least a build-up circuit structure 44 formed on the semiconductor chip 43 and the second carrier plate 401, wherein the build-up circuit structure 44 is electrically connected to a conductive pad 431a located on the semiconductor chip 43 by the means of a conductive via 402b.

The semiconductor chip 43 comprises a non-active surface 430 and an active surface 431. The conductive pad 431a is formed on the active surface 431 of the semiconductor chip 43, and the non-active surface 430 of the semiconductor chip 43 is mounted on the first carrier plate 400 and in a recess formed by the opening 401a of the second carrier plate 401 using the thermally conductive adhesive layer 42. Therefore, heat generated by the semiconductor chip 43 during operation can be directly dissipated using a thermally conductive path formed by the thermally conducive adhesive layer 42 and the carrier structure 40.

The build-up circuit structure 44 which is formed on the semiconductor chip 43 and the second carrier plate 401 comprises at least a dielectric layer 402, a circuit layer 403 crossly superimposed with the dielectric layer 402, and a plurality of conducive vias 402b formed penetrating through the dielectric layer 402 for electrically connecting the circuit layer. The conductive via 402b can be electrically connected to the conductive pad 431a located on the semiconductor chip 43 embedded in the opening 401a of the second carrier plate 401. Furthermore, a plurality of conducive pads 404 is formed on a surface circuit layer of the build-up circuit structure 44 for mounting a plurality of conductive elements such as solder balls 406, such that the semiconductor chip 43 embedded in the carrier structure can be electrically connected to an external device by the means of the conductive pad 431a provided on the surface thereof, the conductive via 402b, the circuit layer 403 and the solder ball 406.

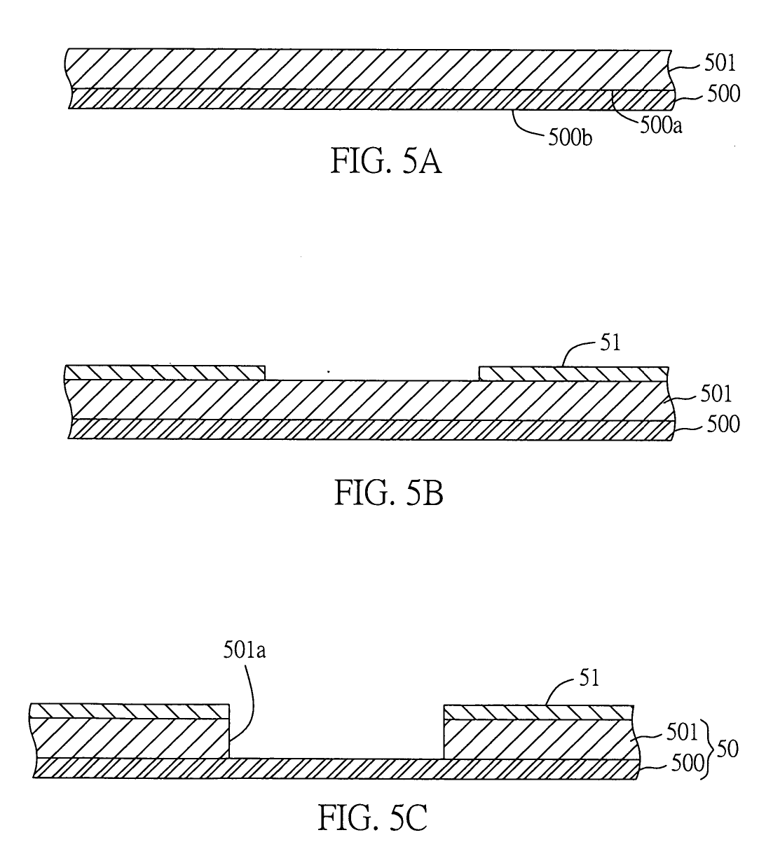

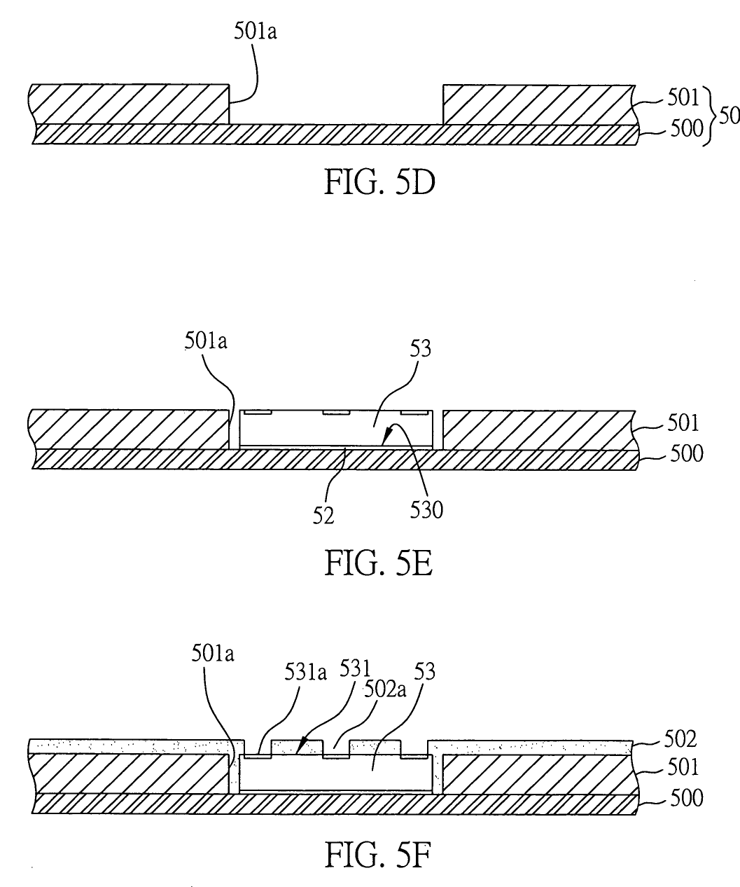

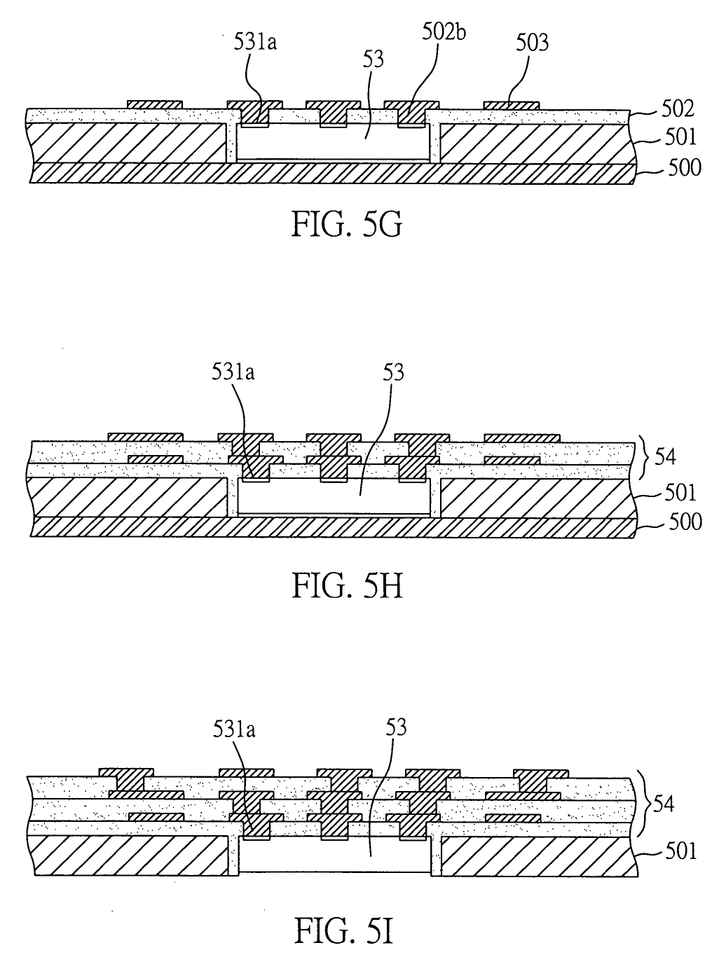

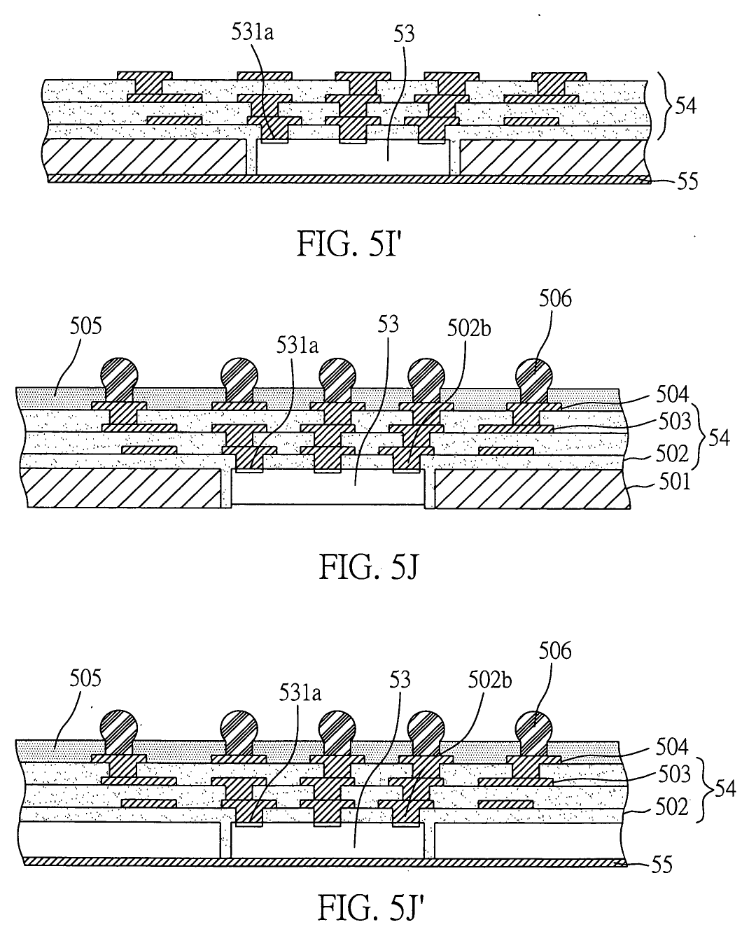

The second embodiment of a method for fabricating a substrate structure with embedded chips of a semiconductor package proposed in the present invention is described in detail with reference to FIG. 5A to FIG. 5J. The second embodiment of the present invention is similar to the first embodiment. The main difference in the second embodiment is that the first carrier plate can be removed to expose the chip, so as to reduce an overall thickness of the structure to meet the requirement of miniaturization while directly attaching other heat dissipating devices to improve heat dissipation efficiency.

Referring to FIG. 5A, first of all, a first carrier plate 500 and a second carrier plate 501 are provided. The first carrier plate 500 is provided with an upper surface 500a and a corresponding lower surface 500b. The second carrier plate 501 can be directly formed on the upper surface 500a. The first carrier plate 500 and the second carrier plate 501 can be optionally selected from combinations of two different metal layers or a ceramic layer and a metal layer. Further, the thickness of the first and second carrier plates 500 and 501 can be determined depending on practical requirements.

Referring to FIG. 5B, the first carrier plate 500 and the second carrier plate 501 are made of different metals, or alternatively, made of a metal and a ceramic, respectively. Then, a patterned resist layer 51 is formed on the second carrier plate 501. The resist layer 51 can be a photoresist layer such as a dry film or liquid photoresist formed on a surface of the second carrier plate 501 using printing, spin-coating or attaching techniques. Subsequently, the resist layer is patterned using exposing and developing techniques, such that the resist layer 51 partially covers the second carrier plate 501.

Referring to FIG. 5C, the first carrier plate 500 and the second carrier plate 501 are made of different metals, or alternatively, are a ceramic plate and a metal plate, respectively. An etching process is performed and the first carrier plate 500 is used as an etching blocking layer. The second carrier plate 501 is optionally etched using an appropriate etchant to remove the second carrier plate 501 that is not covered by the resist layer 51, such that an opening 501a penetrating through the second carrier plate 501 is formed. Thus, a carrier structure 50 having a plurality of openings on a surface thereof for subsequently mounting electronic elements is accomplished. As the carrier structure 50 is made of two different materials, a flat integration surface between the first carrier plate 500 and the second carrier plate 501 of the carrier structure 50 can be achieved, so that the electronic element such as the semiconductor chip can be stably and consistently mounted on the carrier structure. Therefore, production yields of fabricating the carrier structure embedded with chips can be improved while well maintaining uniformity of the integration surface between the carrier structure and the chip. Furthermore, a fabrication quality of a subsequent build-up circuit structure and reliability of electrical connection can also be improved. Moreover, referring to the foregoing fabrication method of the carrier structure 50 made of metals, the opening with the flat integration surface is formed by an optional etching process. Alternatively, a patterned resist layer (not shown) can also be initially formed on the first carrier plate 500. Then, a second carrier plate 501 is formed on surfaces of the first carrier plate 500 free of being subsequently provided with electronic elements by an electroplating process, such that a flat integration surface can be formed between the first carrier plate 500 and the second carrier plate 501.

Referring to FIG. 5D, the resist layer 51 can be removed using a photoresist-stripping process. The process of removing the resist layer 51 is known in the prior-art, and thus is not further described. If the first and second carrier plates are optionally made of a metal and a ceramic, an opening can be formed penetrating through the ceramic using a precast-sintering process, such that a double-layered carrier structure as shown in FIG. 5D can be fabricated. Additionally, the second carrier plate is directly formed on the first carrier plate without using an attaching method.

Referring to FIG. 5E, a non-active surface 530 of a semiconductor chip 53 is mounted on the first carrier plate 500 and embedded in the opening 501a of the second carrier plate 501 using a thermally conductive adhesive layer 52. The dimension of the opening 501a is designed depending on the dimension of the semiconductor chip 53.

Referring to FIG. 5F, a dielectric layer 502 is formed on an active surface 531 of the semiconductor chip 53 and the second carrier plate 501 and filled in the opening 501a penetrating through the second carrier plate. Also, a plurality of conductive pads 531a is provided on the active surface 531 of the chip 53. The dielectric layer 502 can be selected from the group consisting of non-photoimageable resins and epoxy resins such as prepges and film typed BT, ABF, PPE, PTFE and the like, or photoimageable resins. Furthermore, a plurality of vias 502a can be formed penetrating through the dielectric layer 502 to expose the conductive pad 531a located on the active surface 531 of the chip 53 using laser drilling or plasma etching techniques. Alternatively, the via 502a can be formed by exposing and developing processes if the dielectric layer is a photoimageable resin.

Referring to FIG. 5G, a patterned circuit layer 503 is formed on the dielectric layer 502. Subsequently, a conductive via 502b is formed corresponding to the via 502a, such that the patterned circuit layer 503 can be electrically connected to the conducive pad 531a located on the active surface 531 of the chip 53 by the means of the conductive via 502b.

Referring to FIG. 5H, build-up circuits can be continuously formed on the carrier structure 50, such that a build-up circuit structure 54 can be formed and electrically connected to the conductive pad 531a located on the chip 53.

Referring to FIG. 5I, the first carrier plate 500 can be removed, such that a surface of the semiconductor chip 53 can be directly exposed, and an overall thickness of the structure can be reduced to meet the requirement of miniaturization. Furthermore, after removing the first carrier plate 500, surface treatment is performed on an exposed surface of the chip 53 and a surface of the carrier plate on the same side. Subsequently, a metal layer 55 is formed on the treated surface of the chip and the carrier plat during subsequent fabrication of the build-up circuit, such that the exposed surface of the chip can be directly contacted to the metal layer 55 to improve heat dissipation efficiency (as shown in FIG. 5I′).

Referring to FIG. 5J, a patterned solder mask layer 505 having a plurality of openings is formed on an outer surface of the build-up circuit structure 54, such that conductive pads 504 located on the outer surface of the build-up circuit structure 54 are exposed. Subsequently, a plurality of conductive elements such as solder balls 506 are formed on the conductive pad 504 located on the outer surface of the build-up circuit structure 54, so that the semiconductor chip 53 can be electrically connected to an external device. Moreover, a plurality of conductive elements such as solder balls 506 is provided on the build-up circuit structure 54 which is connected to the chip 53 being directly attached to the metal layer 55 shown in FIG. 5I′, such that the chip 53 can be electrically connected to an external device (as shown in FIG. 5J′).

Therefore, referring to FIG. 5J and FIG. 5J′, the substrate structure with embedded chips of the semiconductor package fabricated by the foregoing method according to the second embodiment of the present invention comprises a semiconductor chip 53 having conductive pads 531a on a surface thereof; a carrier plate 501 for receiving the periphery of the semiconductor chip 53; and a build-up circuit structure 54 formed on the carrier plate 501 embedded with the semiconductor chip 53, wherein conductive vias 502b are formed penetrating through the build-up circuit structure 54 to electrically connect the conductive pad 531a located on the semiconductor chip 53, so as to expose a surface of the chip without forming the conductive pad. Additionally, a metal layer 55 can be attached to a surface of the semiconductor chip 53 free of electrically connecting the build-up circuit structure.

The build-up circuit structure 54 which is formed on the semiconductor chip 53 and the second carrier plate 501 comprises at least a dielectric layer 502, a circuit layer 503 crossly superimposed with the dielectric layer 502, and a plurality of conducive vias 502b formed penetrating through the dielectric layer 502 for electrically connecting the circuit layer 503. The conductive via 502b can be electrically connected to the conductive pad 531a located on the semiconductor chip 53. Furthermore, a plurality of conducive pads 504 is formed on a surface circuit layer of the build-up circuit structure 54 for mounting a plurality of conductive elements such as solder balls 506, such that the semiconductor chip 53 can be electrically connected to an external device by the means of the conductive pad 531a provided on the surface thereof, the conductive via 502b, the circuit layer 503 and the solder ball 506.

Referring to the substrate structure with embedded chips of a semiconductor package and the method for fabricating the same proposed in the present invention, at least a semiconductor chip is attached to a heat dissipating carrier structure by the means of a thermally conductive adhesive layer, such that heat generated by the semiconductor chip during operation can be effectively dissipated. Further, the semiconductor chip is embedded in the opening penetrating through the second carrier plate of the carrier structure, such that an overall thickness of the semiconductor device can be reduced to meet the requirement of miniaturization. Also, in the present invention, at least a build-up circuit structure is directly formed on the carrier structure embedded with the semiconductor chip, and the build-up circuit structure can be electrically connected to the conductive pad located on the semiconductor chip by the means of the conducive via. Moreover, the conductive elements such as solder balls can be provided on the outer surface of the build-up circuit structure, such that the semiconductor package structure can be electrically connected to an external device. As the carrier structure of the present invention consists of two different materials such as two different metal layers or a ceramic layer in combination to a metal layer, a flat integration surface can be formed in the second carrier plate using an etching, electroplating or precast-sintering technique. Therefore, an electronic element such as the semiconductor chip can be stably and consistently mounted on the carrier structure, such that production yields of fabricating the carrier structure embedded with chips can be improved while well maintaining uniformity of the integration surface between the carrier structure and the chip. Furthermore, a fabrication quality of the subsequent build-up circuit structure and reliability of electrical connection can be also improved.

Referring to the other embodiment of the present invention, the first carrier plate can be removed to directly expose the chip, such that the overall thickness of the semiconductor package structure can be reduced to effectively meet the requirement of miniaturization while directly attaching other external heat dissipating devices to improve heat dissipation efficiency.

The present invention is capable of integrating the heat dissipating carrier structure, the semiconductor chip and the build-up circuit structure while incorporating techniques of fabricating the semiconductor package, so that drawbacks caused by the semiconductor packaging technique known in the prior-art can be eliminated while solving a surface integration problem of the semiconductor device. Therefore, the present invention is able to provide a substrate structure embedded with chips characterized with advantages including a good quality, high production yield, low cost and good reliability. The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A method for fabricating a substrate structure with an embedded chip of a semiconductor package, comprising steps of:
providing a carrier structure comprising a first carrier plate and a second carrier plate being directly formed on the first carrier plate, the second carrier plate being formed with at least an opening penetrating therethrough;
mounting at least a semiconductor chip on the first carrier plate and embedding the semiconductor chip in the opening of the second carrier plate, the semiconductor chip being provided with a plurality of conductive pads on a surface thereof;
fabricating build-up circuits, such that a dielectric layer is formed on a surface of the chip and the second carrier plate and a material of the dielectric layer is filled in a gap between the opening of the second carrier plate and the chip;
forming vias penetrating through the dielectric layer to expose the conductive pad of the chip; and
forming a patterned circuit layer on the dielectric layer and forming a conductive via in the via, such that the circuit layer can be electrically connected to the conducive pad located on the chip.

2. The method for fabricating a substrate structure with an embedded chip of a semiconductor package of claim 1, wherein materials of the first carrier plate and the second carrier plate are selected from the group consisting of a combination of different metals or a combination of a metal and a ceramic.

3. The method for fabricating a substrate structure with an embedded chip of a semiconductor package of claim 1, wherein the carrier structure is fabricated by the steps of:
attaching the second carrier plate to the first carrier plate;
forming a patterned resist layer on the second carrier plate; and
performing an optionally etching process on the second carrier plate exposed from the patterned resist layer, such that a portion of the second carrier plate is removed to expose the first carrier plate.

4. The method for fabricating a substrate structure with an embedded chip of a semiconductor package of claim 1, wherein the carrier structure is fabricated by the steps of:
forming a patterned resist layer on the first carrier plate; and
performing an electroplating process on the first carrier plate, in order for the second carrier plate having an opening penetrating therethrough to mount on the first carrier plate.

5. The method for fabricating a substrate structure with an embedded chip of a semiconductor package of claim 2, wherein fabrication of the carrier structure is carried out by forming an opening in the ceramic portion by a precast-sintering process, such that a double-layered carrier structure is formed.

6. The method for fabricating a substrate structure with an embedded chip of a semiconductor package of claim 1, further comprising a step of fabricating the build-up circuit to form a build-up circuit structure on the semiconductor chip and the second carrier plate.

7. The method for fabricating a substrate structure with an embedded chip of a semiconductor package of claim 6, further comprising a step of providing conductive elements on an outer surface of the build-up circuit structure.

8. The method for fabricating a substrate structure with an embedded chip of a semiconductor package of claim 1, further comprising a step of removing the first carrier plate, such that a surface of the semiconductor chip is exposed.

9. The method for fabricating a substrate structure with an embedded chip of a semiconductor package of claim 8, further comprising a step of performing surface treatment on an exposed surface of the chip and a surface of the carrier plate located on the same side, such that a metal layer is formed on the treated surface during fabrication of the build-up circuit.

10. The method for fabricating a substrate structure with an embedded chip of a semiconductor package of claim 1, wherein the semiconductor chip is mounted on the first carrier plate and embedded in a recess formed by the opening of the second carrier plate by a thermally conducive adhesive layer.

11. A substrate structure with an embedded chip of a semiconductor package, comprising:
a carrier structure comprising a first carrier plate and a second carrier plate being directly formed on the first carrier plate, the second carrier plate being formed with at least an opening penetrating therethrough;
at least a semiconductor chip embedded in the opening penetrating through the second carrier plate and mounted on the first carrier plate, the semiconductor chip being provided with conductive pads on a surface thereof; and
a build-up circuit structure formed on the second carrier plate and the semiconductor chip, the build-up structure being formed with a plurality of conductive vias to electrically connect the conductive pad located on the semiconductor chip.

12. The substrate structure with an embedded chip of a semiconductor package of claim 11, wherein a plurality of conductive elements is provided on an outer surface of the build-up circuit structure.

13. The substrate structure with an embedded chip of a semiconductor package of claim 11, wherein the build-up circuit structure comprises a dielectric layer, a circuit layer superimposed with the dielectric layer and conductive vias formed penetrating through the dielectric layer.

14. The substrate structure with an embedded chip of a semiconductor package of claim 11, wherein materials of the first carrier plate and the second carrier plate of the carrier structure are selected from the group consisting of a combination of different metals or a combination of a metal and a ceramic.

15. A substrate structure with an embedded chip of a semiconductor package, comprising:
a semiconductor chip having conductive pads on a surface thereof;
a carrier plate for receiving peripheries of the semiconductor chip; and
at least a build-up circuit structure formed on a surface of the carrier plate embedded with the semiconductor chip and the semiconductor chip, the build-up circuit structure being formed with conducive vias for electrically connecting the conducive pad located on the semiconductor chip, such that a surface of the chip without forming the conductive pad is exposed.

16. The substrate structure with an embedded chip of a semiconductor package of claim 15, further comprising a metal layer attached on a surface of the semiconductor chip free of electrically connecting the build-up circuit structure.

17. The substrate structure with an embedded chip of a semiconductor package of claim 15, wherein the build-up circuit structure comprises a dielectric layer, a circuit layer superimposed with the dielectric layer and conductive vias formed penetrating through the dielectric layer.

18. The substrate structure with an embedded chip of a semiconductor package of claim 15, wherein a plurality of conductive elements is provided on an outer surface of the build-up circuit structure.

19. The substrate structure with an embedded chip of a semiconductor package of claim 15, wherein a material of the carrier plate is selected from the group consisting of a metal and a ceramic.
